(19) United States
(12) Patent Application Publication
(10) Pub. No.: US 2018/0308812 A1
(43) Pub. Date: Oct. 25, 2018

(54) SEMICONDUCTOR DEVICE

(71) Applicant: TOYOTA JIDOSHA KABUSHIKI KAISHA, Toyota-shi (JP)

(72) Inventor: Naoya TAKE, Toyota-shi (JP)

(73) Assignee: TOYOTA JIDOSHA KABUSHIKI KAISHA, Toyota-shi (JP)

(21) Appl. No.: 15/936,763

(22) Filed: Mar. 27, 2018

(30) Foreign Application Priority Data
Apr. 19, 2017 (JP) 2017-083034

(51) Int. Cl. H01L 23/00

(52) U.S. Cl. CPC H01L 24/05; H01L 24/06; H01L 24/48; H01L 2224/0612; H01L 2224/05624; H01L 2224/48824; H01L 2224/05638; H01L 2224/04042; H01L 2224/05557; H01L 2224/05573; H01L 2924/386; H01L 2924/0483; H01L 2224/4845

(57) ABSTRACT

A semiconductor device may include a semiconductor substrate, a first bonding pad provided on an upper surface of the semiconductor substrate and constituted of a metal including aluminum, and a second bonding pad provided on the upper surface of the semiconductor substrate. An upper surface of the first bonding pad may be inclined such that positions on the upper surface of the first bonding pad which are closer to the second bonding pad are positioned further above.

### TECHNICAL FIELD

The disclosure herein relates to a semiconductor device.

### BACKGROUND

A semiconductor device is known that includes a semiconductor substrate on an upper surface of which a bonding pad constituted of a metal including aluminum is provided. When a wire is bonded to the bonding pad, the bonding pad is deformed by stress applied to the bonding pad at the bonding. Consequently, the metal that constitutes the bonding pad is ejected from a bonded portion with the wire to an outside of the bonded portion. This phenomenon is called an aluminum splash. When the aluminum splash reaches a vicinity of another bonding pad, an insulating distance between the bonding pads is shortened, and there may be a risk of a short circuit.

Japanese Patent Application Publication No. 2012-109419 discloses a bonding pad that includes a recess on its surface. The recess is disposed around a region to which a wire is to be bonded. When a wire is bonded to the bonding pad, an aluminum splash caused by the bonding enters the recess. Accordingly, the aluminum splash is suppressed from spreading to an outside of the bonding pad. Therefore, a short circuit between the aluminum splash and another bonding pad is suppressed.

### SUMMARY

In a semiconductor device of Japanese Patent Application Publication No. 2012-109419, if a bonding position of the wire is displaced, there may be a case where an aluminum splash does not suitably enter the recess, and hence the wire needs to be bonded accurately to the bonding pad. The disclosure herein provides a technology that suppresses a short circuit between bonding pads due to an aluminum splash by using a configuration different from that of Japanese Patent Application Publication No. 2012-109419.

A semiconductor device disclosed herein may comprise a semiconductor substrate, a first bonding pad provided on an upper surface of the semiconductor substrate and constituted of a metal including aluminum, and a second bonding pad provided on the upper surface of the semiconductor substrate. An upper surface of the first bonding pad may be inclined such that positions on the upper surface of the first bonding pad which are closer to the second bonding pad are positioned further above.

An aluminum splash occurs obliquely upward with respect to an upper surface of a bonding pad. In the semiconductor device described above, the upper surface of the first bonding pad is inclined such that positions on the upper surface of the first bonding pad which are closer to the second bonding pad are positioned further above. Accordingly, an aluminum splash occurring at the first bonding pad on a second bonding pad side occurs at an angle by which the aluminum splash is oriented to be further inclined with respect to an upper surface of the semiconductor substrate, as compared with a case where the upper surface of the first bonding pad is not inclined. Accordingly, a distance by which the aluminum splash protrudes from the first bonding pad toward the second bonding pad in a lateral direction is shortened, and the aluminum splash is less likely to be in contact with the second bonding pad. Therefore, even if an aluminum splash occurs when a wire is bonded, a short circuit between the first bonding pad and the second bonding pad can be suppressed suitably. Moreover, with this configuration, the short circuit between the first bonding pad and the second bonding pad can be suppressed regardless of a bonding position on the first bonding pad. Therefore, the bonding position of a wire on the first bonding pad does not require very high accuracy. According to this configuration, the short circuit between the first bonding pad and the second bonding pad can be suppressed more easily.

### BRIEF DESCRIPTION OF THE DRAWINGS

FIG. 1 is a plan view of a semiconductor device 10.

FIG. 2 is a cross-sectional view along a line II-II in FIG. 1, illustrating a state before a wire bonding.

FIG. 3 is a cross-sectional view along the line II-II in FIG. 1, illustrating a state after the wire bonding.

FIG. 4 is a cross-sectional view (that corresponds to FIG. 3) of a semiconductor device of a comparative example, illustrating a state after a wire bonding.

### DETAILED DESCRIPTION

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved semiconductor device, as well as methods for using and manufacturing the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

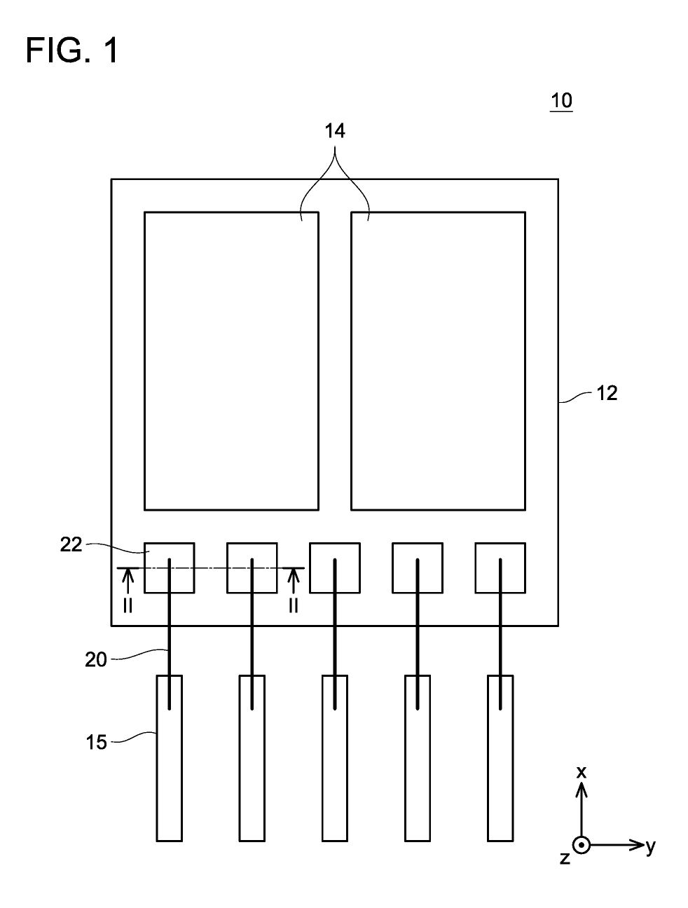

FIG. 1 shows an upper surface of a semiconductor device 10. The semiconductor device 10 includes a semiconductor substrate 12. The semiconductor substrate 12 is constituted of a semiconductor that mainly contains Si (silicon). It should be noted that the semiconductor substrate 12 may be constituted of a wide-band-gap semiconductor that mainly contains SiC (silicon carbide), GaN (gallium nitride), or the like. On an upper surface of the semiconductor substrate 12, main electrodes 14 and a plurality of signal bonding pads 22 are provided. A size of each signal bonding pad 22 is smaller than a size of each main electrode 14. The main electrodes 14 are respectively connected to wiring members, which is not shown, by solder. A plurality of lead wires 15 is disposed adjacent to one side of the semiconductor substrate 12. Each of the signal bonding pads 22 is connected to a corresponding one of the lead wires 15 by a wire 20 constituted of a metal including copper (hereinafter referred to as a copper wire 20). Moreover, although not shown, a lower electrode is provided on a lower surface of the semiconductor substrate 12. The lower electrode is connected to a wiring member, which is not shown, by solder. In the following, as shown in FIG. 1, one direction along the upper surface of the semiconductor substrate 12 is referred to as an x direction, a direction along the upper surface of the semiconductor substrate 12 and orthogonal to the x direction is referred to as a y direction, and a thickness direction of the semiconductor substrate 12 is referred to as a z direction.

Each of the signal bonding pads 22 is constituted of, for example, Al (aluminum) or a metal including aluminum such as AlSi (aluminum silicon). The signal bonding pads 22 are arranged with intervals therebetween in the y direction. In the present embodiment, five of the signal bonding pads 22 are arranged with intervals therebetween in the y direction. The signal bonding pads 22 include, for example, a signal bonding pad that outputs a voltage indicating a temperature of the semiconductor substrate 12, a signal bonding pad that outputs a voltage indicating a value of a current that flows in the semiconductor substrate 12, a signal bonding pad that serves as a gate pad of the semiconductor substrate 12, and the like.

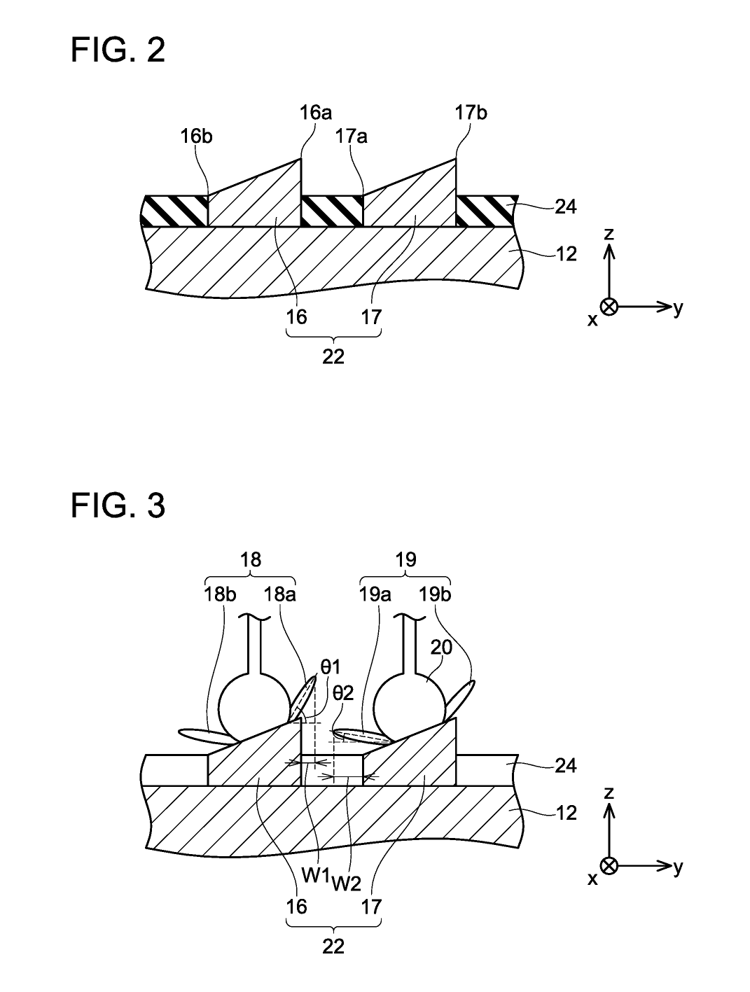

FIG. 2 illustrates a cross section of the semiconductor device 10 along a line II-II in FIG. 1. FIG. 2 illustrates a state before the copper wires 20 are bonded. FIG. 2 illustrates two of the plurality of signal bonding pads 22. In the following, the signal bonding pad 22 on a left side in FIG. 2 is referred to as a first bonding pad 16, and the signal bonding pad 22 on a right side in FIG. 2 is referred to as a second bonding pad 17.

The first bonding pad 16 and the second bonding pad 17 are provided on the upper surface of the semiconductor substrate 12. An insulating film 24 is provided on the upper surface of the semiconductor substrate 12 in a range where neither the first bonding pad 16 nor the second bonding pad 17 is provided.

In ranges where the first bonding pad 16 and the second bonding pad 17 are disposed, the upper surface of the semiconductor substrate 12 is flat. An upper surface of the first bonding pad 16 is inclined such that positions on the upper surface of the first bonding pad 16 which are closer to the second bonding pad 17 are positioned further above. In other words, the upper surface of the first bonding pad 16 is inclined such that a height of the first bonding pad 16 becomes larger at positions on its upper surface which are closer to the second bonding pad 17. It should be noted that, in the disclosure herein, the height of a bonding pad means a distance between the upper surface of the bonding pad and the upper surface of the semiconductor substrate 12, when measured vertically with respect to the upper surface of the semiconductor substrate 12.

An upper surface of the second bonding pad 17 is inclined such that positions on the upper surface of the second bonding pad 17 which are farther away from the first bonding pad 16 are positioned further above. In other words, the upper surface of the second bonding pad 17 is inclined such that a height of the second bonding pad 17 becomes larger at positions on its upper surface which are farther away from the first bonding pad 16. The upper surface of the first bonding pad 16 and the upper surface of the second bonding pad 17 are approximately parallel to each other.

An end portion 16a of the upper surface of the first bonding pad 16 on a second bonding pad 17 side is positioned above an end portion 17a of the upper surface of the second bonding pad 17 on a first bonding pad 16 side. In other words, the height of the first bonding pad 16 at the end portion 16a is larger than the height of the second bonding pad 17 at the end portion 17a. The height of the first bonding pad 16 at an end portion 16b, which is opposite to the end portion 16a, approximately coincides with the height of the second bonding pad 17 at the end portion 17a. Moreover, the height of the first bonding pad 16 at the end portion 16a approximately coincides with the height of the second bonding pad 17 at an end portion 17b. The end portion 16b and the end portion 17a are positioned above the insulating film 24.

FIG. 3 is a diagram illustrating a state where the copper wire 20 is bonded to each of the first bonding pad 16 and the second bonding pad 17. When the copper wires 20 are to be bonded, a capillary, which is not shown, is moved in an approximately vertical direction with respect to the upper surface of the semiconductor substrate 12, and a load is thereby imposed to a tip (a ball portion) of each of the copper wires 20 in the vertical direction. When the copper wire 20 is bonded to the first bonding pad 16, a metal that exists at a bonding position (metal that constitutes the first bonding pad 16) is pushed out by the copper wire 20, and an aluminum splash 18 thereby occurs as shown in FIG. 3. Similarly, when the copper wire 20 is bonded to the second bonding pad 17, an aluminum splash 19 occurs.

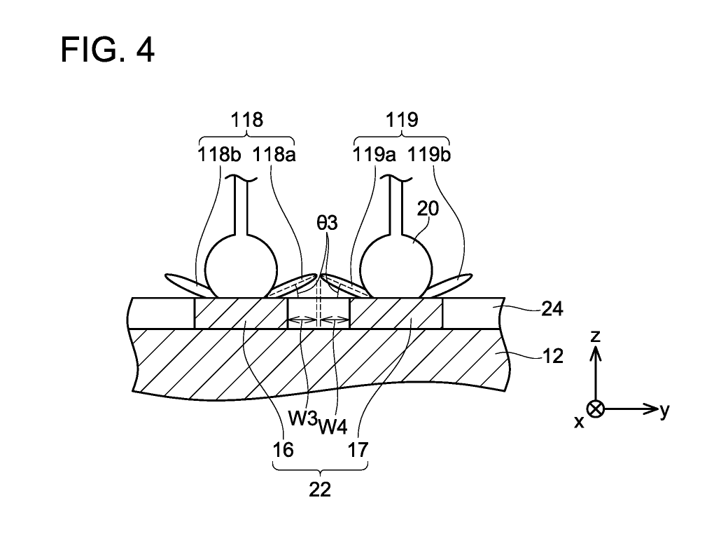

An aluminum splash is formed to extend obliquely upward at a predetermined angle with respect to an upper surface of a bonding pad. As shown in a comparative example in FIG. 4, if the upper surfaces of the signal bonding pads 22 are not inclined, each of aluminum splashes 118 and 119 is formed to extend obliquely upward from its corresponding signal bonding pad 22, while being inclined at a fixed angle θ3 with respect to a horizontal plane (i.e., a plane parallel to the upper surface of the semiconductor substrate 12). In contrast to this, at the first bonding pad 16 in FIG. 3, the upper surface of the first bonding pad 16 is inclined such that positions on the upper surface of the first bonding pad 16 which are closer to the second bonding pad 17 are positioned further above. Accordingly, a portion 18a of the aluminum splash 18 on the second bonding pad side is formed to extend obliquely upward from the first bonding pad 16, while being inclined at an angle θ1 which is larger than the angle θ3. In other words, the portion 18a extends to be further inclined with respect to the upper surface of the semiconductor substrate 12 than a portion 118a of the conventional aluminum splash. Accordingly, as shown in FIGS. 3 and 4, between a distance W1 by which the portion 18a protrudes from the first bonding pad 16 in a lateral direction and a distance W3 by which the portion 118a protrudes from the bonding pad 16 in the lateral direction, a relationship of W1<W3 is established.

At the second bonding pad 17 in FIG. 3, the upper surface of the second bonding pad 17 is inclined such that positions on the upper surface of the second bonding pad 17 which are farther away from the first bonding pad 16 are positioned further above. Accordingly, a portion 19a of the aluminum splash 19 on the first bonding pad side is formed to extend obliquely upward from the second bonding pad 17, while being inclined at an angle θ2 which is smaller than the angle θ3. In other words, the portion 19a extends to be less inclined than a portion 119a of the conventional aluminum splash. Accordingly, as shown in FIGS. 3 and 4, between a distance W2 by which the portion 19a protrudes from the second bonding pad 17 in the lateral direction and a distance W4 by which the portion 119a protrudes from the second bonding pad 17 in the lateral direction, a relationship of W2>W4 is established. It should be noted that a difference between the distance W2 and the distance W4 is small.

Moreover, at the second bonding pad 17, a portion 19b of the aluminum splash 19, which is opposite to the portion 19a, is formed to extend obliquely upward from the second bonding pad 17, while being inclined at an angle larger than the angle θ3, similarly to the portion 18a. In other words, the portion 19b extends to be further inclined than a portion 119b of the conventional aluminum splash. Accordingly, a distance by which the portion 19b protrudes from the second bonding pad 17 in the lateral direction is shorter than a distance by which the portion 119b protrudes from the second bonding pad 17 in the lateral direction.

Moreover, at the first bonding pad 16, a portion 18b of the aluminum splash 18, which is opposite to the portion 18a, is formed to extend obliquely upward from the first bonding pad 16, while being inclined at an angle smaller than the angle θ3, similarly to the portion 19a. In other words, the portion 18b extends to be less inclined than a portion 118b of the conventional aluminum splash. Accordingly, a distance by which the portion 18b protrudes from the first bonding pad 16 in the lateral direction is longer than a distance by which the portion 118b protrudes from the first bonding pad 16 in the lateral direction.

As mentioned above, the relationship of W1<W3 and the relationship of W2>W4 are established among W1 to W4. It should be noted that a difference between the distance W1 and the distance W3 is large, whereas the difference between the distance W2 and the distance W4 is not so large. Accordingly, a relationship of W1+W2<W3+W4 is established. As such, as compared with the comparative example shown in FIG. 4, in the embodiment shown in FIG. 3, a total distance by which the portions 18a and 19a of the aluminum splashes protrude respectively from the first bonding pad 16 and the second bonding pad 17 in the lateral direction can be shortened between the first bonding pad 16 and the second bonding pad 17. Therefore, an insulating distance between the portion 18a of the aluminum splash occurring at the first bonding pad 16 and the portion 19a of the aluminum splash occurring at the second bonding pad 17 can be increased.

Moreover, the end portion 16a of the upper surface of the first bonding pad 16 is positioned above the end portion 17a of the upper surface of the second bonding pad 17. Accordingly, an insulating distance between the aluminum splash 18 occurring at the first bonding pad 16 and the second bonding pad 17 can be increased in the thickness direction (z direction) of the semiconductor substrate.

As such, even if an aluminum splash occurs when the copper wire 20 is bonded, a short circuit between the first bonding pad 16 and the second bonding pad 17 can be suppressed suitably.

Moreover, the upper surface of the second bonding pad 17 is inclined such that positions on the upper surface of the second bonding pad 17 which are farther away from the first bonding pad 16 are positioned further above. In other words, both of the upper surface of the first bonding pad 16 and the upper surface of the second bonding pad 17 are inclined upward toward a y-axis positive direction. Accordingly, a wire bonding can be performed on each of the first bonding pad 16 and the second bonding pad 17 under an approximately same condition (a load, a stroke, and the like). In particular, in the present embodiment, since the upper surface of the first bonding pad 16 and the upper surface of the second bonding pad 17 are approximately parallel to each other, an approximately same bonding condition can be adopted for the first bonding pad 16 and the second bonding pad 17.

Moreover, although not shown, upper surfaces of other signal bonding pads 22 are inclined similarly to those of the first bonding pad 16 and the second bonding pad 17. Therefore, the insulating distance can be secured between aluminum splashes of each pair of the signal bonding pads 22. Moreover, the bonding can be performed on the respective signal bonding pads 22 under the approximately same condition.

Some of the technical features disclosed herein will be listed below. It should be noted that the respective technical elements are independent of one another, and are useful solely or in combinations . . . .

In a configuration disclosed herein as an example, an end portion of an upper surface of a first bonding pad on a second bonding pad side may be positioned above an end portion of an upper surface of the second bonding pad on a first bonding pad side.

According to this configuration, an insulating distance between an aluminum splash occurring at the first bonding pad and the second bonding pad can be increased in the thickness direction of the semiconductor substrate. A short circuit between the first bonding pad and the second bonding pad can therefore be suppressed.

In a configuration disclosed herein as an example, the second bonding pad may be constituted of a metal including aluminum, and the upper surface of the second bonding pad may be inclined such that positions on the upper surface of the second bonding pad which are farther away from the first bonding pad are positioned further above.

According to this configuration, both of the upper surface of the first bonding pad and the upper surface of the second bonding pad are inclined in a same direction with respect to the semiconductor substrate. Accordingly, wire bonding can be performed on the first bonding pad and the second bonding pad under similar conditions.

In a configuration disclosed herein as an example, a semiconductor device may further comprise a first wire connected to the first bonding pad and constituted of a metal including copper, and a second wire connected to the second bonding pad and constituted of a metal including copper.

Since a wire including copper is hard, an aluminum splash is thereby likely to occur.

Therefore, using the inclined bonding pad with the wire including copper is more advantageous.

Specific examples of the present invention has been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A semiconductor device comprising:
a semiconductor substrate;
a first bonding pad provided on an upper surface of the semiconductor substrate and constituted of a metal including aluminum; and
a second bonding pad provided on the upper surface of the semiconductor substrate,
wherein
an upper surface of the first bonding pad is inclined such that positions on the upper surface of the first bonding pad which are closer to the second bonding pad are positioned further above.

2. The semiconductor device of claim 1, wherein
an end portion of the upper surface of the first bonding pad on a second bonding pad side is positioned above an end portion of an upper surface of the second bonding pad on a first bonding pad side.

3. The semiconductor device of claim 1, wherein
the second bonding pad is constituted of a metal including aluminum, and
the upper surface of the second bonding pad is inclined such that positions on the upper surface of the second bonding pad which are farther away from the first bonding pad are positioned further above.

4. The semiconductor device of claim 1 further comprising:
a first wire connected to the first bonding pad and constituted of a metal including copper; and
a second wire connected to the second bonding pad and constituted of a metal including copper.
